(19) United States
(12) Patent Application Publication
(10) Pub. No.: US 2024/0396533 A1
(43) Pub. Date: Nov. 28, 2024

(54) OSCILLATION RING CIRCUIT AND APPARATUS AND METHOD FOR MEASURING READING TIME OF SEQUENTIAL CIRCUIT

(71) Applicants: HEXIN Technologies Co., Ltd., Guangzhou (CN); HEXIN Technologies (Suzhou) Co., Ltd., Suzhou (CN)

(72) Inventor: Liezhi WU, Guangzhou (CN)

(73) Assignees: HEXIN Technologies Co., Ltd., Guangzhou (CN); HEXIN Technologies (Suzhou) Co., Ltd., Suzhou (CN)

(21) Appl. No.: 18/655,872

(22) Filed: May 6, 2024

(30) Foreign Application Priority Data
May 23, 2023 (CN) 202310591460.5

(51) Int. Cl. H03K 3/03; H03K 3/037; H03K 19/20

(52) U.S. Cl. CPC H03K 3/0322; H03K 3/037; H03K 19/20

(57) ABSTRACT

Oscillation ring circuits and apparatuses and methods for measuring reading time of sequential circuit are provided. An oscillation ring circuit includes an odd number of oscillatory circuits connected in series, each including a first clock generator circuit, a flip-flop circuit and a first inverter circuit connected in series. Within an oscillatory circuit, output end of clock generator circuit is connected to clock signal input end of flip-flop circuit; data output end of flip-flop circuit is connected to input end of first inverter circuit; output end of first inverter circuit is connected to input end of first clock generator circuit and data input end of flip-flop circuit within another oscillatory circuit. Another oscillation ring circuit is formed by replacing one flip-flop circuit with a sequential circuit to be measured. Reading time of the sequential circuit is measured according to changes in waveforms of oscillation periods of oscillation ring circuits.

### CROSS-REFERENCE TO RELATED APPLICATION

This application claims priority to Chinese Patent Application No. 202310591460.5, filed on May 23, 2023, which is hereby incorporated by reference in its entirety.

### TECHNICAL FIELD

The present application relates to the field of technologies for measuring reading time of sequential circuits and, in particular, to oscillation ring circuits and an apparatus and method for measuring reading time of a sequential circuit.

### BACKGROUND

In design of an integrated circuit, a sequential circuit generally refers to a circuit device with a data storage function, where a data storing or reading behavior is triggered by a clock signal, such as a flip-flop (flip-flop), an on-chip memory (memory), and so on. The performance of the sequential circuit has a significant impact on the overall performance of the integrated circuit.

Access time of the sequential circuit is an important indicator of the circuit performance. Shorter access time means that data can be written to or read from the sequential circuit within shorter time. The access time can be further subdivided into memory time and reading time. For a simple sequential device, such as a flip-flop, once data is written, its state is immediately reflected on a data output port, therefore the writing time and the reading time thereof are identical. For a complex sequential circuit, such as an on-chip memory, writing and reading operations thereof are performed through different ports, or even triggered by different clocks, thus the memory time and the reading time are different.

In the prior art, a way of measuring reading time of a sequential circuit by simulation has a relatively high error, which affects the maximum performance of the sequential circuit, so it is necessary to provide a new solution.

### SUMMARY

The present application provides oscillation ring circuits and an apparatus and method for measuring reading time of a sequential circuit, in order to solve the technical problem of a relatively high error in measuring reading time of a sequential circuit using simulation technology, which affects the maximum performance of the sequential circuit, and to realize accurate and easy measurement of the reading time of the sequential circuit.

To solve the above technical problem, in a first aspect, embodiments of the present application provide an oscillation ring circuit of a first type, including an odd number of identical oscillatory circuits, where the oscillatory circuits are sequentially connected in series to form the oscillation ring circuit, each of the oscillatory circuits comprises a first clock generator circuit, a flip-flop circuit and a first inverter circuit, and the number of the oscillatory circuits is at least three; where,
within an oscillatory circuit, an output end of the first clock generator circuit is connected to a clock signal input end of the flip-flop circuit; a data output end of the flip-flop circuit is connected to an input end of the first inverter circuit;
an output end of the first inverter circuit is connected to an input end of the first clock generator circuit within another oscillatory circuit and a data input end of the flip-flop circuit within the another oscillatory circuit.

According to the above technical solution, taking into account characteristics of a conventional oscillation ring circuit, the first clock generator circuit, the flip-flop circuit and the first inverter circuit form the oscillatory circuit, and the odd number of the oscillatory circuits are sequentially connected in series to form the oscillation ring circuit. The flip-flop circuit, as a basic unit of the oscillation ring circuit, has a simple structure, and a single-stage time delay of a sequential circuit can be measured according to a change obtained by comparing periods of output oscillation waveforms in a case of inputting a level disturbance to be identified. Measurement of reading time of the sequential circuit is realized on a hardware circuit, which is simple in structure, and compared with a stimulation method, a more accurate performance indicator of an actual circuit can be obtained and simulation data can be corrected.

According to the first aspect, in a first possible implementation of the first aspect, the first clock generator circuit includes a second inverter circuit and an exclusive-OR gate circuit; where
an output end of the second inverter circuit is connected to a first input end of the exclusive-OR gate circuit;
an output end of the exclusive-OR gate circuit is connected to the clock signal input end of the flip-flop circuit within a respective oscillatory circuit;
an input end of the second inverter circuit and a second input end of the exclusive-OR gate circuit are both connected to the output end of the first inverter circuit within another oscillatory circuit.

According to the above technical solution, the clock generator circuit is used to trigger the flip-flop circuit to take samples for its data input end, so as to transform an output signal of a data output end of a flip-flop into the same signal as that of a data input end of the flip-flop. This clock flip-flop has a simple structure and stable data.

According to the first aspect, in the first possible implementation of the first aspect, the first inverter circuit and the second inverter circuit are identical.

According to the above technical solution, same devices are selected for the first inverter circuit and the second inverter circuit to ensure the stability of a feedback level waveform outputted by the oscillatory circuit.

According to the first aspect, in the first possible implementation of the first aspect, the oscillatory circuits include three oscillatory circuits.

According to the above technical solution, the greater the number of the oscillatory circuits is, the longer the period of the output feedback level waveform is, and the smaller the effect of a single oscillatory circuit or a sequential circuit to be measured on the period of the output feedback level waveform is, which then reduces the measurement accuracy of the single oscillatory circuit or the sequential circuit to be measured. The optimal measurement result can be obtained with three oscillatory circuits.

According to the first aspect, in a second possible implementation of the first aspect, a time delay of the second inverter circuit is larger than a minimum pulse width of the flip-flop circuit.

According to the above technical solution, in the actual circuit, considering that the flip-flop driven by a clock generator has a requirement of the minimum pulse width for the clock signal, there is a certain requirement for the time delay of the second inverter circuit, which must be designed to be larger than the minimum pulse width of the flip-flop, with being slightly larger than the minimum pulse width of the flip-flop as the best effect.

In a second aspect, embodiments of the present application provide an oscillation ring circuit of a second type, including an even number of oscillatory circuits and a circuit to be measured, where the circuit to be measured is connected in series with the oscillatory circuits to form the oscillation ring circuit, each of the oscillatory circuits includes a first clock generator circuit, a flip-flop circuit and a first inverter circuit, and the circuit to be measured includes a second clock generator circuit, a sequential circuit to be measured and a third inverter circuit; where,
within an oscillatory circuit, an output end of the first clock generator circuit is connected to a clock signal input end of the flip-flop circuit; a data output end of the flip-flop circuit is connected to an input end of the first inverter circuit;
an output end of the first inverter circuit is connected to an input end of the first clock generator circuit within another oscillatory circuit and a data input end of the flip-flop circuit within the another oscillatory circuit, or to an input end of the second clock generator circuit within the circuit to be measured and an address input end of the sequential circuit to be measured within the circuit to be measured;
an output end of the second clock generator circuit within the circuit to be measured is connected to a clock signal input end of the sequential circuit to be measured;
a data output end of the sequential circuit to be measured is connected to an input end of the third inverter circuit;
an output end of the third inverter circuit is connected to an input end of the first clock generator circuit within any one oscillatory circuit and a data input end of the flip-flop circuit within the any one oscillatory circuit.

According to the above technical solution, based on the oscillation ring circuit of the first type, one of the oscillatory circuits of the oscillation ring circuit of the first type is replaced with a complex circuit to be measured, and the remaining even number of oscillatory circuits and the circuit to be measured are connected in series to form the oscillation ring circuit. The composition of the oscillatory circuit is the same as that of the oscillatory circuit in the oscillation ring circuit of the first type, and the circuit to be measured includes the second clock generator circuit, the sequential circuit to be measured and the third inverter circuit. According to the change obtained by comparing the periods of the output oscillation waveforms, a time delay of the complex sequential circuit to be measured can be measured. Measurement of reading time of the sequential circuit is realized on a hardware circuit, which is simple in structure, and compared with a stimulation method, a more accurate performance indicator of an actual circuit can be obtained and simulation data can be corrected.

According to the second aspect, in a first possible implementation of the second aspect, the first clock generator circuit and the second clock generator circuit each include a second inverter circuit and an exclusive-OR gate circuit, where,
an output end of the second inverter circuit is connected to a first input end of the exclusive-OR gate circuit;
an output end of the exclusive-OR gate circuit is connected to a clock signal input end of the flip-flop circuit within a respective oscillatory circuit or the clock signal input end of the sequential circuit to be measured;
an input end of the second inverter circuit and a second input end of the exclusive-OR gate circuit are both connected to an output end of the first inverter circuit within another oscillatory circuit or an output end of the third inverter circuit within the circuit to be measured.

According to the above technical solution, the clock generator circuit is used to trigger the flip-flop circuit to take samples for its data input end, so as to transform an output signal of a data output end of a flip-flop into the same signal as that of a data input end of the flip-flop. This clock flip-flop has a simple structure and stable data. According to the second aspect, in the first possible implementation of the second aspect, the first inverter circuit, the second inverter circuit and the third inverter circuit are identical.

According to the above technical solution, same devices are selected for the first inverter circuit, the second inverter circuit and the third inverter circuit to ensure the stability of a feedback level waveform outputted by the oscillatory circuit.

According to the second aspect, in the first possible implementation of the second aspect, the oscillatory circuits include two oscillatory circuits.

According to the above technical solution, the greater the number of the oscillatory circuits, the longer the period of the output feedback level waveform, and the smaller the effect of the sequential circuit to be measured on the period of the output feedback level waveform, which then reduces the measurement accuracy of the sequential circuit to be measured. The optimal measurement result can be obtained by a combination of two oscillatory circuits and one circuit to be measured.

According to the second aspect, in the first possible implementation of the second aspect, the sequential circuit to be measured is an on-chip memory circuit.

According to the above technical solution, the on-chip memory circuit is typically a more complex sequential circuit in common use, and its performance has a significant impact on the overall performance of an integrated circuit.

According to the second aspect, in a second possible implementation of the second aspect, a time delay of the second inverter circuit is larger than a minimum pulse width of the flip-flop circuit.

According to the above technical solution, in the actual circuit, considering that the flip-flop driven by a clock generator has a requirement of the minimum pulse width for the clock signal, there are certain requirements for the time delay of the second inverter circuit, which must be designed to be larger than the minimum pulse width of the flip-flop, with being slightly larger than the minimum pulse width of the flip-flop as the best result.

In a third aspect, embodiments of the present application also provide an apparatus of a first type for measuring reading time of a sequential circuit. The apparatus includes a comparative unit and a test unit, where the comparative unit includes the oscillation ring circuit of the first type as described above, and the test unit includes the oscillation ring circuit of the second type as described above.

According to the above technical solution, using the oscillation ring circuit of the first type provided in the present application as the comparative unit and the oscillation ring circuit of the second type as the test unit can realize a clear layout and a simple structure.

According to the third aspect, in a first possible implementation of the third aspect, the apparatus further includes a data processing unit, and the data processing unit is connected to the comparative unit and test unit respectively;
the comparative unit is configured to output a first feedback level waveform according to an inputted identifiable level disturbance;
the test unit is configured to output a second feedback level waveform according to the same inputted identifiable level disturbance;
the data processing unit is configured to: obtain an oscillation period of the first feedback level waveform according to the first feedback level waveform, and obtain an oscillation period of the second feedback level waveform according to the second feedback level waveform; calculate a difference between the oscillation period of the first feedback level waveform and the oscillation period of the second feedback level waveform; calculate reading time of the sequential circuit to be measured according to the difference and a time delay of the flip-flop circuit.

According to the above technical solution, the time delay of the complex sequential circuit to be measured can be measured according to the change obtained by comparing the oscillation periods of the feedback level waveforms outputted by the comparative unit and the test unit. The apparatus for measuring reading time of a sequential circuit on a hardware circuit is provided, which has a simple structure, and a more accurate performance indicator of an actual circuit is obtained and simulation data is corrected.

According to the third aspect, in a first possible implementation of the third aspect, the reading time of the sequential circuit to be measured is calculated by the following formula:

$${Tcq}^{′} = Tdelta / 2 + T c q ,$$

where Tdelta denotes the difference between the oscillation period of the second feedback level waveform and the oscillation period of the first feedback level waveform, and Tcq denotes the time delay of the flip-flop circuit.

According to the above technical solution, the formula for calculating the reading time of the sequential circuit to be measured is obtained by letting the theoretical difference between the oscillation period of the second feedback level waveform and the oscillation period of the first feedback level waveform be equal to the measured difference therebetween.

In a fourth aspect, embodiments of the present application also provide an apparatus of a second type for measuring reading time of a sequential circuit. The apparatus includes a test module, a switch module and first oscillatory circuits which are sequentially connected in series;
the test module includes a second oscillatory circuit and a circuit to be measured which are connected in parallel;
the first oscillatory circuits and the second oscillatory circuit are each the oscillatory circuit as described above; the circuit to be measured is the circuit to be measured as described above;
an input end of the switch module is connected to an output end of one of the first oscillatory circuits, and the switch module includes two output ends, one of which is connected to an input end of the second oscillatory circuit, and the other of which is connected to an input end of the circuit to be measured;
an output end of the second oscillatory circuit and an output end of the circuit to be measured are both connected to an input end of another first oscillatory circuit.

According to the above technical solution, the first oscillatory circuits are used as a common portion; the second oscillatory circuit and the circuit to be measured are connected in parallel; and the switching of the second oscillatory circuit and the circuit to be measured is realized by the switch module. The oscillation ring circuit of the first type and the oscillation ring circuit of the second type provided in the present application are integrated together, which further simplifies the circuit structure.

In a fifth aspect, embodiments of the present application also provide a method for measuring reading time of a sequential circuit, which includes:
inputting an identifiable level disturbance into the oscillation ring circuit of the first type as described above, and obtaining a first feedback level waveform by oscillation processing;
inputting the same identifiable level disturbance into the oscillation ring circuit of the second type as described above, and obtaining a second feedback level waveform by oscillation processing;
obtaining an oscillation period of the first feedback level waveform according to the first feedback level waveform, and obtaining an oscillation period of the second feedback level waveform according to the second feedback level waveform;
calculating a difference between the oscillation period of the first feedback level waveform and the oscillation period of the second feedback level waveform;
calculating reading time of the sequential circuit to be measured according to the difference and a time delay of the flip-flop circuit.

According to the above technical solution, the same level disturbance is input into the oscillation ring circuit of the first type and the oscillation ring circuit of the second type, respectively, and by analyzing changes in the oscillation periods of the feedback level waveforms outputted by the oscillation ring circuit of the first type and the oscillation ring circuit of the second type, the time delay of the complex sequential circuit to be measured can be measured. The method for measuring the reading time of the sequential circuit on a hardware circuit is obtained, which is simple in structure, and a more accurate performance indicator of an actual circuit is obtained and simulation data is corrected.

According to the fifth aspect, in a first possible implementation of the fifth aspect, the reading time of the sequential circuit to be measured is calculated by the following formula:

$${Tcq}^{′} = Tdelta / 2 + T c q ,$$

where Tdelta denotes the difference between the oscillation period of the second feedback level waveform and the oscillation period of the first feedback level waveform, and Tcq denotes the time delay of the flip-flop circuit.

According to the above technical solution, the formula for calculating the reading time of the sequential circuit to be measured is obtained by letting the theoretical difference between the oscillation period of the second feedback level waveform and the oscillation period of the first feedback level waveform be equal to the measured difference therebetween.

The embodiments of the present application provide oscillation ring circuits and an apparatus and method for measuring reading time of a sequential circuit. An oscillation ring circuit of one type is formed by an odd number of identical oscillatory circuits sequentially connected in series, each of the oscillatory circuits including a first clock generator circuit, a flip-flop circuit and a first inverter circuit which are sequentially connected in series; within an oscillatory circuit, an output end of the first clock generator circuit is connected to a clock signal input end of the flip-flop circuit; a data output end of the flip-flop circuit is connected to an input end of the first inverter circuit; an output end of the first inverter circuit is connected to an input end of the first clock generator circuit and a data input end of the flip-flop circuit within another oscillatory circuit. An oscillation ring circuit of another type is formed by replacing one of the flip-flop circuits therein with a sequential circuit to be measured. In the present application, the reading time of the sequential circuit to be measured is measured according to changes in oscillation periods of feedback level waveforms of the two types of oscillation ring circuits. Measurement of the reading time of the sequential circuit is realized on a hardware circuit, which is simple in structure and accurate in measurement, and simulation data is corrected.

### BRIEF DESCRIPTION OF DRAWINGS

FIG. 1 is a diagram of an oscillation ring circuit of a first type provided by embodiments of the present application.

FIG. 2 is a diagram of an oscillation ring circuit provided by embodiments of the present application and an oscillation ring circuit with a test target circuit.

FIG. 3 is a circuit diagram of an implementation of an oscillation ring circuit of a first type provided by embodiments of the present application.

FIG. 4 is a circuit diagram of another implementation of an oscillation ring circuit of a first type provided by embodiments of the present application.

FIG. 5 is a waveform diagram of a clock generator provided by embodiments of the present application.

FIG. 6 is a state transition diagram of an oscillation ring circuit of a sequential circuit provided by embodiments of the present application.

FIG. 7 is a diagram of an oscillation ring circuit of a second type provided by embodiments of the present application.

FIG. 8 is a circuit diagram of an implementation of an oscillation ring circuit of a second type provided by embodiments of the present application.

FIG. 9 is a circuit diagram of another implementation of an oscillation ring circuit of a second type provided by embodiments of the present application.

FIG. 10 is a schematic diagram of an architecture of an apparatus of a first type for measuring reading time of a sequential circuit provided by embodiments of the present application.

FIG. 11 is a schematic diagram of another architecture of an apparatus of a first type for measuring reading time of a sequential circuit provided by embodiments of the present application.

FIG. 12 is a schematic diagram of an architecture of an apparatus of a second type for measuring reading time of a sequential circuit provided by embodiments of the present application.

FIG. 13 is a schematic diagram of a principle of a dual-control switch provided by embodiments of the present application.

FIG. 14 is a schematic diagram of steps of a method for measuring reading time of a sequential circuit provided by embodiments of the present application.

### REFERENCE SIGNS ARE AS FOLLOWS

1—oscillatory circuit, 101—first clock generator circuit, 102—flip-flop circuit, 103—first inverter circuit, 1011—second inverter circuit, 1012—exclusive-OR gate circuit, 2—circuit to be measured, 201—second clock generator, 202—sequential circuit to be measured, 203—third inverter circuit, 3—comparative unit, 4—test unit, 5—data processing unit, 6—test module, 7—switch module, 8—first oscillatory circuit, 9—second oscillatory circuit.

### DESCRIPTION OF EMBODIMENTS

The following embodiments of the present application are specifically elucidated in conjunction with the accompanying drawings. The embodiments are given for illustrative purposes only and are not to be construed as a limitation of the present application, and the accompanying drawings are included for reference and illustrative purposes only, and do not constitute a limitation on the scope of patent protection of the present application. Based on the embodiments in the present application, all other embodiments obtained by persons of ordinary skill in the art without creative effort fall within the scope of protection of the present application.

### Embodiment 1

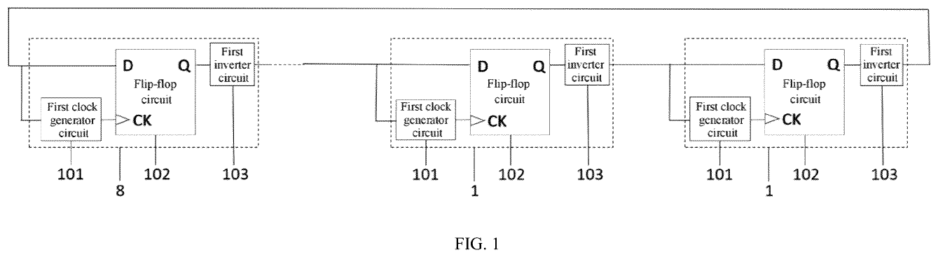

Please refer to FIG. 1, in an embodiment of the present application, an oscillation ring circuit of a first type for measuring reading time of an external circuit is disclosed, including an odd number of identical oscillatory circuits 1. The oscillatory circuits 1 are sequentially connected in series to form the oscillation ring circuit. Each of the oscillatory circuits 1 includes a first clock generator circuit 101, a flip-flop circuit 102 and a first inverter circuit 103. The number of the oscillatory circuits is at least three.

Within the oscillatory circuit 1, an output end of the first clock generator circuit 101 is connected to a clock signal input end of the flip-flop circuit 102; a data output end of the flip-flop circuit is connected to an input end of the first inverter circuit 103; an output end of the first inverter circuit 103 is connected to an input end of the first clock generator circuit 101 and a data input end of the flip-flop circuit 102 within another oscillatory circuit 1.

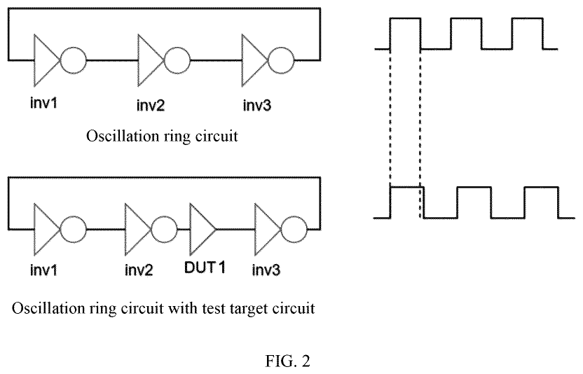

A conception of the technical solution of the present application is based on the idea of a conventional oscillation ring circuit. As shown in FIG. 2, an oscillation ring circuit as well as an oscillation ring circuit with a test target circuit DUT1 are shown, where the oscillation ring circuit is formed by three inverter circuits. When a level disturbance identifiable as 0 or 1 occurs at an input end of an inverter inv1, the inverter will generate a level representing a logical inverse with a certain time delay to be fed back to the input end of inv1, and this logically inverse level will be propagated through three stages of inverters and then logically inverted again. As a result, at an output end of any of the three stages of the inverters, a waveform that flips at a certain frequency can be seen, and the magnitude of the frequency depends on the sum of time delays of the inverters.

By measuring an oscillation period of an output waveform of the oscillation ring circuit, information on a time delay of a single-stage inverter circuit can be obtained. Effects of variables such as a process deviation, a temperature and a voltage on the performance of the inverter circuit can be obtained by comparing changes in the time delays of the inverter circuit under different process deviations, temperatures and voltages, which is a common practice in modern integrated circuit design.

Making use of the characteristic of the conventional oscillation ring circuit, it is possible to measure time delay characteristics of some simple circuits. For example, for measuring a time delay of a buffer, a buffer can be connected into an oscillation ring circuit, and the buffer circuit to be measured will increase the time delay of the oscillation ring circuit and thus extend the oscillation period of the output waveform of the oscillation ring circuit, which ultimately results in an increase in the oscillation period of the waveform that flips and a decrease in frequency. The time delay of the buffer to be measured can be measured by comparing the change in the oscillation periods of the output waveforms.

The output waveform can be outputted out of chip via IO circuits, and its accurate period can be measured by instruments such as oscilloscopes.

Tdut is used to denote the time delay of the test target circuit DUT1, which is calculated by the formula:

$$T d u t = ( T c y cle 2 - Tcycle 1 ) / 2 ,$$

where Tcycle1 denotes the oscillation period of the waveform outputted by the oscillation ring circuit without the buffer to be measured being connected therein; and
Tcycle2 denotes the oscillation period of the waveform outputted by the oscillation ring circuit with the buffer to be measured being connected therein.

Based on the above idea of the oscillation ring circuit formed by the inverters, the present application provides a new oscillation ring circuit. An oscillatory circuit of the oscillation ring circuit is formed by a sequential circuit, and can be used to measure a single-stage time delay of the sequential circuit.

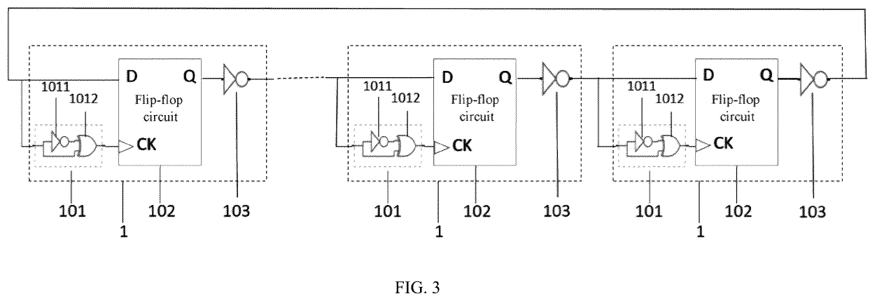

Flip-flop is one of the most typical basic sequential circuits in modern digital circuit design. As shown in FIG. 3, in an embodiment of the present application, an oscillation ring circuit with a D flip-flop circuit as the basic unit is provided. The D flip-flop circuit has a simple structure, and once data is written into it, its state is immediately reflected on an output data port, therefore writing time and reading time thereof are the same, and the oscillation ring circuit formed by it has a little effect on a change in a period of an output waveform.

The oscillation ring circuit provided in the embodiment of the present application uses the flip-flop circuit as the basic unit of the oscillation ring circuit, which has a simple structure, and the single-stage time delay of the sequential circuit can be measured according to a change obtained by comparing the oscillation periods of output feedback level waveforms in a case of inputting a level disturbance to be identified. The present application realizes measurement of reading time of the sequential circuit on a hardware circuit, which is simple in structure, and a more accurate performance indicator of an actual circuit can be obtained and simulation data can be corrected.

As shown in FIG. 1, in the embodiment of the present application, the oscillation ring circuit includes an odd number of identical oscillatory circuits 1, and the oscillatory circuits 1 are sequentially connected in series to form the oscillation ring circuit. Each of the oscillatory circuits 1 includes the first clock generator circuit 101, the flip-flop circuit 102 and the first inverter circuit 103. Within the oscillatory circuit 1, the output end of the first clock generator circuit 101 is connected to the clock signal input end of the flip-flop circuit 102; the data output end of the flip-flop circuit 102 is connected to the input end of the first inverter circuit 103; and the output end of the first inverter circuit 103 is connected to the input end of the first clock generator circuit 101 and the data input end of the flip-flop circuit 102 within another oscillatory circuit 1.

In order to understand the working principle of the new-type oscillation ring circuit in the present application which uses the flip-flop as the basic unit, it is first necessary to understand the working principle of a clock generator.

As shown in FIG. 3, the first clock generator circuit 101 includes a second inverter circuit 1011 and an exclusive-OR gate circuit 1012, where an output end of the second inverter circuit 1011 is connected to a first input end of the exclusive-OR gate circuit 1012; an output end of the exclusive-OR gate circuit 1012 is connected to the clock signal input end of the flip-flop circuit 102 within the respective oscillatory circuit 1; and an input end of the second inverter circuit 1011 and a second input end of the exclusive-OR gate circuit 1012 are both connected to the output end of the first inverter circuit 103 within another oscillatory circuit 1.

The exclusive-OR gate circuit 1012 is to implement an exclusive-or logic gate in digital logic and has a plurality of input ends and one output end, and a multi-input exclusive-OR gate circuit may be formed by two-input exclusive-OR gate circuits. If level states (0 or 1) of the two inputs are different, the output is a high level 1. If the level states of the two inputs are the same, the output is a low level 0. In other words, if the two inputs have different level states, the exclusive-OR gate circuit outputs a high level 1.

As shown in FIG. 5, a schematic diagram of a working principle of a clock generator is shown. It is assumed that the input end (point a) of the clock generator circuit is fed by a continuously inverted waveform, which is formed into a waveform at point b after being subject to a time delay and inversion of the second inverter circuit. The waveform at point a and the waveform at point b pass through the exclusive-OR gate circuit, and then a waveform at point c is generated. Observation of the waveform at point c shows that as long as the waveform at point a has a rising edge or a falling edge, a rising edge will be generated at point c after passing through the clock generator circuit, and the width of the high level of the waveform at point c depends on the time delay of the second inverter circuit.

The clock generator circuit is used to trigger the flip-flop circuit to take samples for its data input end, so as to transform an output signal of the data output end of the flip-flop into the same signal as that of the data input end of the flip-flop. This clock flip-flop has a simple structure and stable data.

In a real circuit, considering that the flip-flop driven by the clock generator circuit has a requirement of the minimum pulse width for the clock signal, there is a certain requirement for the time delay of the second inverter circuit, which must be designed to be larger than the minimum pulse width of the flip-flop circuit, and being slightly larger than the minimum pulse width of the flip-flop circuit is optimal.

The first inverter circuit 103 and the second inverter circuit 1011 are the same. In other words, the first inverter circuit 103 and the second inverter circuit 1011 have the same circuit structure and constituent devices, or are the same inverters, in order to ensure the stability of the feedback level waveform outputted by the oscillatory circuit.

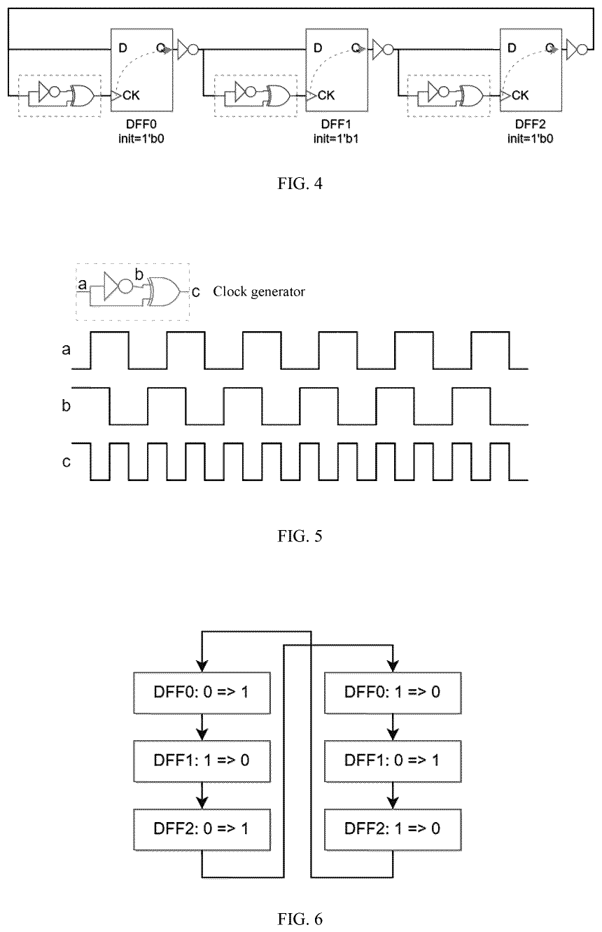

In the new-type oscillation ring circuit disclosed in the present application, the number of the oscillatory circuits 1 has a certain effect on the oscillation period of the feedback level waveform outputted by the oscillation ring circuit. The greater the number of the oscillatory circuits 1 is, the longer the oscillation period of the feedback level waveform outputted by the oscillatory circuits is, and the smaller the effect of a single oscillatory circuit on the oscillation period of the output feedback level waveform is, which in turn reduces the measurement accuracy of the oscillation ring circuit disclosed in the present application. Therefore, as shown in FIG. 4, an oscillation ring circuit formed by using three oscillatory circuits 1 in the present application can achieve an optimal measurement effect.

As shown in FIG. 4, taking the oscillation ring circuit formed by three oscillatory circuits as an example, each oscillatory circuit includes a first clock generator circuit. D flip-flop circuits within the respective oscillatory circuits are labeled DFF0, DFF1 and DFF2, and an output end of the D flip-flop circuit is connected to a first inverter circuit.

In the oscillation ring circuit disclosed in the embodiment of the present application as shown in FIG. 4, it is assumed that there is an identifiable level disturbance at a data input end D of DFF0, and this disturbance will likewise act on an input end of the first clock generator circuit that drives DFF0 and generate a rising edge waveform through the first clock generator circuit. The rising edge waveform will trigger DFF0 to take samples for its own data input end D, thereby transforming an output signal of a data output end Q of DFF0 into the same signal as that of the data input end D of DFF0, and this signal change will be passed to the first clock generator circuit and the flip-flop circuit of the next oscillatory circuit after being inverted by the first inverter connected to the data output end Q of DFF0. The same signal change but with an opposite polarity then occurs at input and output ends of DFF1. Eventually, this signal change will be passed to the data input end of DFF0 through a jump in the input and output of DFF2 and have the opposite polarity, thereby forming an oscillation.

The above process can be represented by a state transition diagram as shown in FIG. 6. If a level disturbance with a state of 0=>1 is input into the data input end of DFF0, a state change of a level disturbance input into the data input end of DFF1 is 1⇒0. In a similar manner, a state of a level disturbance input into the data input end of DFF2 is 0⇒1, and this signal change is passed to the data input end of DFF0 and has the opposite polarity, thus forming an oscillation.

The oscillation ring circuit of the first type provided in the embodiments of the present application is used to solve the technical problems of a low accuracy and an effect on the maximum performance of a sequential device in measurement of a sequential circuit by means of simulation. The flip-flop circuit is used as the basic unit of the oscillation ring circuit, which has a simple structure, and the single-stage time delay of the sequential circuit can be measured according to the change obtained by comparing the oscillation periods of the output feedback level waveforms.

Measurement of the reading time of the sequential circuit is realized on a hardware circuit, which is simple in structure, and a more accurate performance indicator of the actual circuit is obtained and simulation data is corrected.

### Embodiment 2

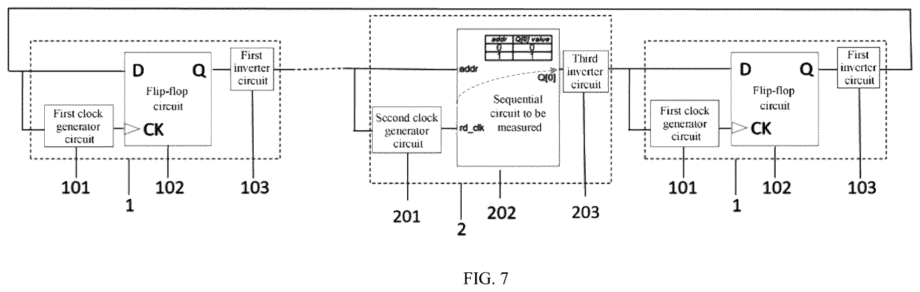

Please refer to FIG. 7, in an embodiment of the present application, an oscillation ring circuit of a second type is provided. The oscillation ring circuit of the second type is based on Embodiment 1, with the flip-flop circuit in one of the oscillatory circuits being replaced with a sequential circuit to be measured, and thus maintains the same oscillation ring structure as that in Embodiment 1 to realize measurement of a time delay of the sequential circuit to be measured. Thus, in the embodiment of the present application, the oscillation ring circuit of the second type includes an even number of oscillatory circuits 1 and one circuit 2 to be measured. The circuit 2 to be measured is connected in series with the oscillatory circuits 1 to form the oscillation ring circuit. Each of the oscillatory circuits 1 includes a first clock generator circuit 101, a flip-flop circuit 102 and a first inverter circuit 103, and the circuit 2 to be measured includes a second clock generator circuit 201, a sequential circuit 202 to be measured and a third inverter circuit 203.

Within the oscillatory circuit 1, an output end of the first clock generator circuit 101 is connected to a clock signal input end of the flip-flop circuit 102; a data output end of the flip-flop circuit is connected to an input end of the first inverter circuit 103;
an output end of the first inverter circuit 103 is connected to an input end of the first clock generator circuit 101 within another oscillatory circuit 1 and a data input end of the flip-flop circuit 102 within another oscillatory circuit 1, or to an input end of the second clock generator circuit 201 within the circuit 2 to be measured and an address input end of the sequential circuit 202 to be measured within the circuit 2 to be measured;
an output end of the second clock generator circuit 201 within the circuit 2 to be measured is connected to a clock signal input end of the sequential circuit 202 to be measured;
a data output end of the sequential circuit 202 to be measured is connected to an input end of the third inverter circuit 203;
an output end of the third inverter circuit 203 is connected to an input end of the first clock generator circuit 101 within any oscillatory circuit land a data input end of the flip-flop circuit 102 within any oscillatory circuit 1.

As shown in FIG. 7, the oscillation ring circuit of the second type is disclosed on the basis of the oscillation ring circuit of the first type provided in the embodiment of the present application, with the flip-flop circuit in one of the oscillatory circuits in the oscillation ring circuit of the second type on the basis of the Embodiment 1 being replaced with the sequential circuit to be measured, and thus maintains the same oscillation ring structure as that in Embodiment 1 to realize the measurement of the time delay of the sequential circuit to be measured.

This embodiment is based on the same characteristics of the D flip-flop described above, that is, the circuit structure is simple, and once data is written into it, its state is immediately reflected on an output data port, thus writing time and reading time thereof are identical, and the oscillation ring circuit formed by it has a little effect on a change in a period of an output waveform. Therefore, a D flip-flop circuit is likewise selected as the flip-flop circuit 102 within each oscillatory circuit in the embodiment of the present application.

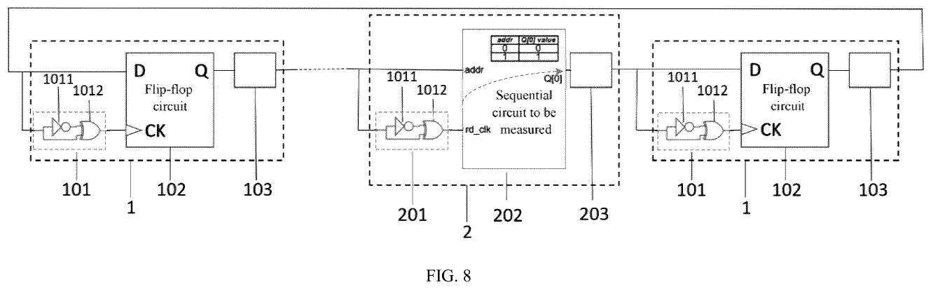

As shown in FIG. 8, the working principle of the clock generator described in Embodiment 1 of the present application is taken as a basis, that is: the clock generator includes an inverter and an exclusive-OR gate circuit, and in this embodiment of the present application, the first clock generator circuit 101 and the second clock generator circuit 201 utilize the same structural composition and devices. The exclusive-OR gate circuit is to implement an exclusive-or logic gate in digital logic and has a plurality of input ends and one output end, and a multi-input exclusive-OR gate circuit may be formed by two-input exclusive-OR gate circuits. If level states (0 or 1) of the two inputs are different, the output is a high level 1. If the level states of the two inputs are the same, the output is a low level 0. In other words, if the two inputs have different level states, the exclusive-OR gate circuit outputs a high level 1.

Within the first clock generator circuit 101 and the second clock generator circuit 201, an output end of the second inverter circuit 1011 is connected to a first input end of the exclusive-OR gate circuit 1012; an output end of the exclusive-OR gate circuit 1012 is connected to the clock signal input end of the flip-flop circuit 102 within the respective oscillatory circuit; an input end of the second inverter circuit 1011 and a second input end of the exclusive-OR gate circuit 1012 are both connected to an output end of the first inverter circuit 103 within another oscillatory circuit 1 or an output end of the third inverter circuit 203 within the circuit 2 to be measured.

As shown in FIG. 5, it is assumed that the input end (point a) of the clock generator circuit is fed by a continuously inverted waveform, which is formed into a waveform at point b after being subject to a time delay and inversion of the inverter. The waveform at point a and the waveform at point b pass through the exclusive-OR gate circuit, and then a waveform at point c is generated. Observation of the waveform at point c shows that as long as the waveform at point a has a rising edge or a falling edge, a rising edge will be generated at point c after passing through the clock generator circuit, and the width of the high level of the waveform at point c depends on the time delay of the inverter.

The oscillation ring circuit of the second type provided by the embodiments of the present application adopts the clock generator circuit with the same structure and device composition as that in the oscillation ring circuit of the first type, so as to trigger the flip-flop circuit to take samples for its data input end, thereby transforming an output signal of the data output end of the flip-flop into the same signal as that of the data input end of the flip-flop. This clock flip-flop is simple in structure and stable in data.

In a real circuit, considering that the flip-flop driven by the clock generator has a requirement of the minimum pulse width for the clock signal, there is a certain requirement for the time delay of the second inverter circuit, which must be designed to be larger than the minimum pulse width of the flip-flop, and being slightly larger than the minimum pulse width of the flip-flop is optimal.

The first inverter circuit 103, the second inverter circuit 1011 and the third inverter circuit 203 are the same. In other words, the first inverter circuit 103, the second inverter circuit 1011 and the third inverter circuit 203 have the same circuit structure and constituent devices, or are the same inverters, in order to ensure the stability of the feedback level waveform outputted by the oscillatory circuit.

In the oscillation ring circuit of the second type disclosed in the present application, the number of the oscillatory circuits 1 has a certain effect on the oscillation period of the feedback level waveform outputted by the oscillation ring circuit. The greater the number of the oscillatory circuits 1 is, the longer the oscillation period of the feedback level waveform outputted by the oscillatory circuits is, and the smaller the effect of the sequential circuit 202 to be measured on the period of the output feedback level waveform is, which in turn reduces the measurement accuracy of the sequential circuit 202 to be measured.

In order to ensure the accuracy of measuring the sequential circuit 202 to be measured by the oscillation ring circuit of the second type in the present application, an optimal measurement effect can be achieved by using the oscillation ring circuit formed by two oscillatory circuits 1 in the present application.

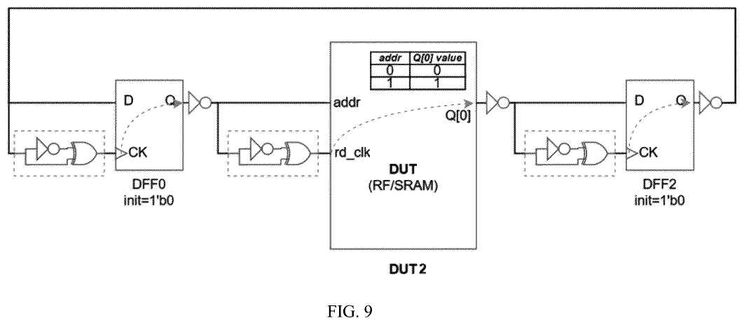

As shown in FIG. 9, taking the oscillation ring circuit formed by two oscillatory circuits and the circuit to be measured as an example, each of the oscillatory circuits includes a first clock generator circuit. D flip-flop circuits within the respective oscillatory circuits are labeled DFF0 and DFF2, and a data output end Q of the D flip-flop circuit is connected to a first inverter circuit.

The circuit to be measured includes a second clock generator circuit, a sequential circuit to be measured (DUT) and a third inverter circuit. A data output end Q[0] of the sequential circuit to be measured is connected to the third inverter circuit, an input end of the second clock generator circuit in the circuit to be measured and an address input end addr of the sequential circuit to be measured are connected to an output end of the first inverter within another oscillatory circuit, and an output end of the second clock generator circuit in the circuit to be measured is connected to a clock signal input end rd_clk of the sequential circuit to be measured.

In a possible embodiment of the oscillation ring circuit of the second type shown in FIG. 9, where the sequential circuit to be measured is an on-chip memory circuit, it is assumed that there is a level disturbance identifiable as 0 or 1 at a data input end D of DFF0, and this disturbance will likewise act on an input end of the first clock generator circuit that drives DFF0 and generate a rising edge waveform through the first clock generator circuit. The rising edge will trigger DFF0 to take samples for its own data input D, thereby transforming an output signal of a data output end Q of DFF0 into the same signal as that of the data input D of DFF0, and this signal change will be passed to the second clock generator circuit and the on-chip memory circuit of the circuit to be measured after being inverted by the first inverter circuit connected to the data output end Q of DFF0. At the moment, the level disturbance state input through the address input point of the on-chip memory circuit is opposite to the level disturbance state input through the data input end D of DFF0, and the disturbance will also act on an input end of the second clock generator circuit that drives the on-chip memory and generate a rising edge waveform through the second clock generator circuit. The rising edge waveform will trigger the on-chip memory to take samples for its own address input end addr, thereby transforming an output signal of the data output end Q[0] of the on-chip memory into a signal having the same specified value corresponding to the address of the input end addr of the on-chip memory, and this signal change will be passed to the first clock generator circuit and flip-flop circuit of the next oscillatory circuit after being inverted by the third inverter connected to the data output end Q[0] of the on-chip memory. Eventually, this signal change will be passed to the data input end of DFF0 through a jump in the input and output of DFF2 and have the opposite polarity, thereby forming an oscillation.

The sequential circuit to be measured in the oscillation ring circuit disclosed in this embodiment is a more complex sequential circuit, namely, the on-chip memory circuit. A reading clock of the on-chip memory circuit is driven by the second clock generator circuit within the circuit to be measured, and built-in data of the on-chip memory is initialized to a specified value. For example, if the address is 0, the corresponding specified value is 0; and if the address is 1, the corresponding specified value is 1. The specified value can ensure that the value read out from the data output end Q[0] of the sequential circuit to be measured and the numerical state of the address end is the same.

The oscillation ring circuit provided in the second embodiment of the present application is used to solve the technical problems of having a low accuracy and affecting the maximum performance of the sequential device in measurement of the complex sequential circuit by means of simulation. On the basis of the oscillation ring circuit provided in the first embodiment of the present application, one of the flip-flop circuits in the oscillation ring circuit in the first embodiment of the present application is replaced with the complex sequential circuit to be measured, and the time delay of the complex sequential circuit to be measured can be measured according to the change obtained by comparing the oscillation periods of the output feedback level waveforms. Measurement of the reading time of the sequential circuit is realized on a hardware circuit, which is simple in structure, and a more accurate performance indicator of the actual circuit is obtained and simulation data is corrected.

### Embodiment 3

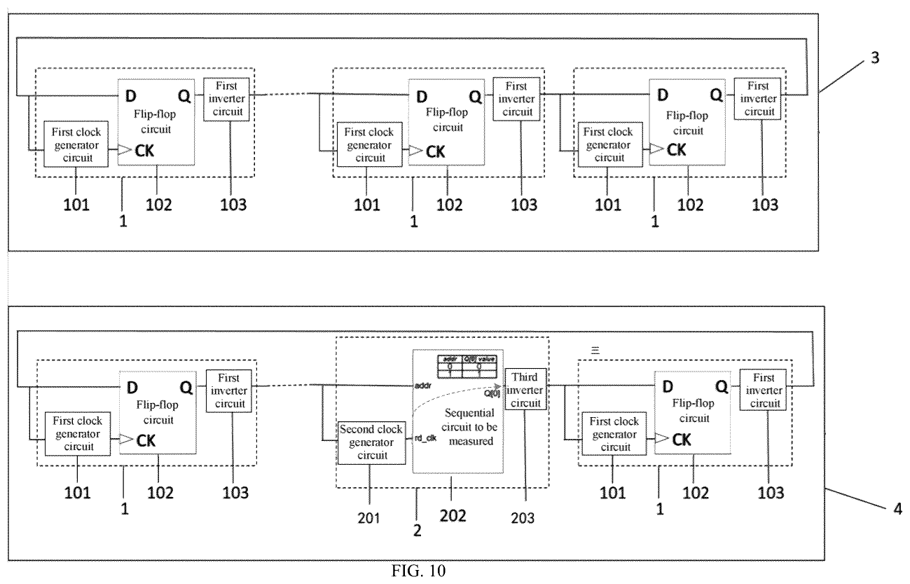

As shown in FIG. 10, according to the oscillation ring circuits provided in Embodiment 1 and Embodiment 2 of the present application, the present application further provides an apparatus of a first type for measuring reading time of a sequential circuit. The apparatus includes a comparative unit 3 and a test unit 4, where the comparative unit 3 includes the oscillation ring circuit as described in Embodiment 1, and the test unit 4 includes the oscillation ring circuit as described in Embodiment 2.

In this embodiment of the present application, the oscillation ring circuit of the first type provided in Embodiment 1 of the present application is used as a comparative unit, and the oscillation ring circuit of the second type provided in Embodiment 2 of the present application is used as a test unit, which has a clear layout and a simple structure.

As shown in FIG. 10, the comparative unit 3 includes an odd number of identical oscillatory circuits 1 that are sequentially connected in series to form the oscillation ring circuit, and each of the oscillatory circuits 1 includes a first clock generator circuit 101, a flip-flop circuit 102 and a first inverter circuit 103. The number of the oscillatory circuits is at least three.

Within the oscillatory circuit of the comparative unit 3, an output end of the first clock generator circuit 101 is connected to a clock signal input end of the flip-flop circuit 102; a data output end of the flip-flop circuit 102 is connected to an input end of the first inverter circuit 103; and an output end of the first inverter circuit 103 is connected to an input end of the first clock generator circuit 101 and a data input end of the flip-flop circuit 102 within another oscillatory circuit 1.

The test unit 4 includes an even number of oscillatory circuits 1 and a circuit 2 to be measured, where the circuit 2 to be measured is connected in series with the oscillatory circuits 1 to form the oscillation ring circuit. Each of the oscillatory circuits 1 includes a first clock generator circuit 101, a flip-flop circuit 102 and a first inverter circuit 103, and the circuit 2 to be measured includes a second clock generator circuit 201, a sequential circuit 202 to be measured and a third inverter circuit 203.

Within the oscillatory circuit 1 of the test unit 4, an output end of the first clock generator circuit 101 is connected to a clock signal input end of the flip-flop circuit 102; a data output end of the flip-flop circuit 102 is connected to an input end of the first inverter circuit 103; an output end of the first inverter circuit 103 is connected to an input end of the first clock generator circuit 101 and a data input end of the flip-flop circuit 102 within another oscillatory circuit 1, or to an input end of the second clock generator circuit 201 and an address input end of the sequential circuit to be measured within the circuit 2 to be measured; an output end of the second clock generator circuit 201 within the circuit 2 to be measured is connected to a clock signal input end of the sequential circuit 202 to be measured; a data output end of the sequential circuit 202 to be measured is connected to an input end of the third inverter circuit 203; an output end of the third inverter circuit 203 is connected to an input end of the first clock generator circuit 101 and a data input end of the flip-flop circuit 102 within any oscillatory circuit 1.

This embodiment is based on the same characteristics of the D flip-flop described above, that is, the circuit structure is simple, and once data is written into it, its state is immediately reflected on an output data port, thus writing time and reading time thereof are identical, and the oscillation ring circuit formed by it has a little effect on a change in a period of an output waveform. Therefore, a D flip-flop circuit is likewise selected as the flip-flop circuit 102 within each oscillatory circuit in the embodiment of the present application.

In this embodiment of the present application, the first clock generator and the second clock generator each include a second inverter circuit and an exclusive-OR gate circuit. The exclusive-OR gate circuit is to implement an exclusive-or logic gate in digital logic and has a plurality of input ends and one output end, and a multi-input exclusive-OR gate circuit may be formed by two-input exclusive-OR gate circuits. If level states (0 or 1) of the two inputs are different, the output is a high level 1. If the level states of the two inputs are the same, the output is a low level 0. In other words, if the two inputs have different level states, the exclusive-OR gate circuit outputs a high level 1.

In a real circuit, considering that the flip-flop driven by the clock generator has a requirement of the minimum pulse width for the clock signal, there is a certain requirement for the time delay of the second inverter circuit, which must be designed to be larger than the minimum pulse width of the flip-flop, and being slightly larger than the minimum pulse width of the flip-flop is optimal.

In this embodiment of the present application, the first inverter circuit, the second inverter circuit, and the third inverter circuit are the same to ensure the stability of the feedback level waveform outputted by the oscillatory circuit. In other words, the first inverter circuit, the second inverter circuit, and the third inverter circuit have the same circuit structure and component devices, or are the same inverters, to ensure the stability of the feedback level waveform outputted by the oscillatory circuit.

In this embodiment of the present application, in order to improve the measurement accuracy of the reading time of the sequential circuit to be measured, the oscillation ring circuit in Embodiment 1 of the present application and the oscillation ring circuit in Embodiment 2 of the present application are integrated in the apparatus for measuring reading time of a sequential circuit, and it is ensured that the same type of flip-flops are selected for the oscillatory circuits in the comparative unit and the oscillatory circuits in the test unit. The first clock generator circuit and the second clock generator circuit also use the same type of devices. The layout and wiring are as consistent as possible, and the sequential circuit to be measured in the test unit is connected into the test unit through ports.

In this embodiment of the present application, in order to improve the measurement accuracy of the reading time of the clock generator to be measured, the number of the oscillatory circuits in the comparative unit is preferably three, and the number of the oscillatory circuits in the test unit is preferably two.

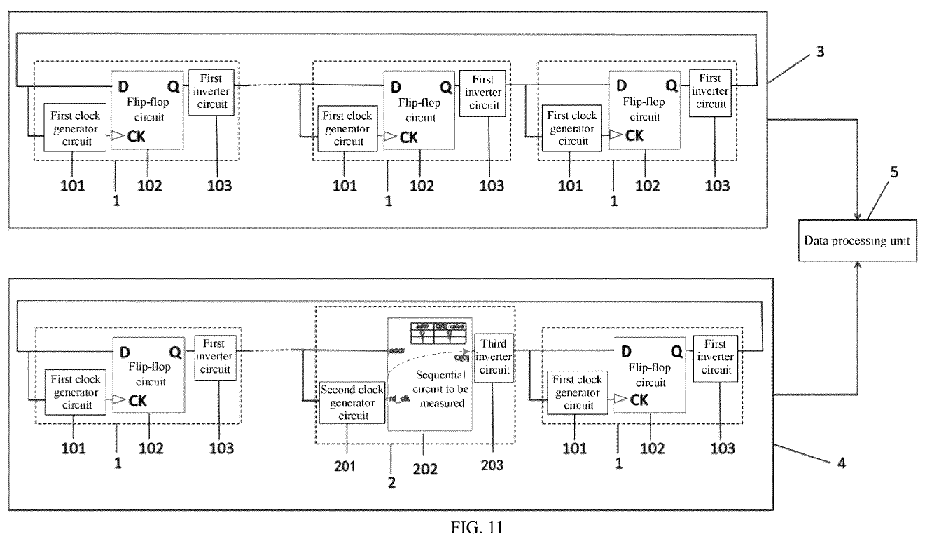

As shown in FIG. 11, in a further implementation of this embodiment of the present application, the apparatus further includes a data processing unit 5, and the data processing unit 5 is connected to the comparative unit 3 and test unit 4 respectively;
the comparative unit 3 is configured to output a first feedback level waveform according to an inputted identifiable level disturbance;
the test unit 4 is configured to output a second feedback level waveform according to the same inputted identifiable level disturbance;
the data processing unit 5 is configured to: obtain an oscillation period of the first feedback level waveform according to the first feedback level waveform, and obtain an oscillation period of the second feedback level waveform according to the second feedback level waveform; calculate a difference between the oscillation period of the first feedback level waveform and the oscillation period of the second feedback level waveform; calculate reading time of the sequential circuit to be measured according to the difference and a time delay of the flip-flop circuit.

The time delay of the complex sequential circuit to be measured can be measured according to the change obtained by comparing the oscillation periods of the feedback level waveforms outputted by the comparative unit and the test unit. The apparatus for measuring reading time of a sequential circuit on a hardware circuit is provided, which has a simple structure, and a more accurate performance indicator of an actual circuit is obtained and simulation data is corrected.

In another possible embodiment of the present application, the reading time of the sequential circuit to be measured is calculated by the following formula:

$${Tcq}^{′} = Tdelta / 2 + T c q ,$$

where Tdelta denotes the difference between the oscillation period of the second feedback level waveform and the oscillation period of the first feedback level waveform, and Tcq denotes the time delay of the flip-flop circuit.

Within the comparative unit, once the oscillation ring circuit starts oscillating, the frequency of its feedback level waveform is determined by the sum of a time delay of the exclusive-OR gate circuit in each of the first clock generator circuits plus time delays from the clock signal input ends CK of all the flip-flop circuits to their data output ends Q. The time delay from the clock signal input end CK of the flip-flop circuit to its data output end Q is an internal time delay of the flip-flop, that is, access time of the flip-flop circuit. For the flip-flop circuits, reading and writing operations are uniform, therefore memory time and reading time will not be discriminated, and instead, they are combined as the access time.

Therefore, the oscillation period of the first feedback level waveform corresponding to the first feedback level waveform outputted by the comparative unit is:

$$Tcycle = ( Tcg + T cq ) ⋆ A ⋆ 2 = ( Tcg + T cq ) ⋆ 2 A ,$$

where Tcycle is the oscillation period of the first feedback level waveform, Tcg is the time delay of the clock generator circuit, Tcq is the time delay of the flip-flop circuit, and A denotes the number of the oscillatory circuits.

Within the test unit, once the oscillation ring circuits start oscillating, the frequency of the feedback level waveform is determined by the sum of a time delay of each of the oscillatory circuits and a time delay of the circuit to be measured. The time delay of each oscillatory circuit is determined by the sum of a time delay of the exclusive-OR gate circuit in the first clock generator circuit thereof plus a time delay from the clock signal input end CK of the flip-flop circuit thereof to its data output end Q. The time delay of the circuit to be measured is determined by the sum of a time delay of the exclusive-OR gate circuit in the second clock generator circuit thereof plus a time delay from the clock signal input end rd_clk of the sequential circuit to be measured to its data output end Q[0].

Therefore, the oscillation period of the second feedback level waveform corresponding to the second feedback level waveform outputted by the test unit is:

$${Tcycle}^{′} = ( Tcg + T cq ) ⋆ 2 ⋆ ( A - 1 ) + 2 ( T cg + {Tcq}^{′} ) ,$$

where Tcycle′ is the oscillation period of the second feedback level waveform, Tcg′ denotes the circuit time delay from the clock input end (rd_clk) of the circuit to be measured to its data output end (Q[0]).

When three oscillatory circuits are used to form the oscillation ring circuit, the oscillation period of the first feedback level waveform of the comparative unit can be expressed as:

$$Tcycle = ( Tcg + T cq ) ⋆ 3 ⋆ 2 = ( Tcg + T cq ) ⋆ 6 ,$$

the oscillation period of the second feedback level waveform of the test unit can be expressed as:

$${Tcycle}^{′} = 4 ( T c g + T c q ) + 2 ( T cg + {Tcq}^{′} ) ,$$

the difference Tdelta between Tcycle′ and Tcycle is calculated as:

$$Tdelta = {Tcycle}^{′} - Tcycle = 4 ( T c g + T c q ) + 2 ( T cg + {Tcq}^{′} ) - 6 ( T c g + T cq )$$

$$= 2 {Tcq}^{′} - 2 Tcq .$$

When five oscillatory circuits are used to form the oscillation ring circuit, the oscillation period of the first feedback level waveform of the comparative unit can be expressed as:

$$Tcycle = ( Tcg + T cq ) ⋆ 5 ⋆ 2 = ( Tcg + T cq ) ⋆ 10 ,$$

the oscillation period of the second feedback level waveform of the test unit can be expressed as:

$${Tcycle}^{′} = 8 ( Tcg + Tcq ) + 2 ( Tcg + {Tcq}^{′} ) ,$$

the difference Tdelta between Tcycle′ and Tcycle is calculated as:

$$Tdelta = {Tcycle}^{′} - Tcycle = 8 ( T c g + T c q ) + 2 ( T cg + {Tcq}^{′} ) - 10 ( T c g + T cq )$$

$$= 2 {Tcq}^{′} - 2 Tcq .$$

Therefore, the difference between Tcycle′ and Tcycle is independent of the number of the oscillatory circuits, so no matter how many oscillatory circuits are used to form the oscillation ring circuit, the difference between Tcycle′ and Tcycle is expressed by the following formula: Tdelta=2Tcq′−2Tcq.

The circuit structure of the flip-flop circuit is relatively simple, and more accurate and reliable values can be obtained by simulation. The simulation method for obtaining the time delay of the flip-flop circuit belongs to the prior art and will not be repeated in the embodiments of the present application.

Therefore, the formula for calculating the reading time of the sequential circuit to be measured is:

$${Tcq}^{′} = Tdelta / 2 + T c q .$$

Specific limitations on the apparatus for measuring reading time of a sequential circuit in this embodiment can be found in the limitations of the oscillation ring circuits in Embodiment 1 and Embodiment 2 above, and will not be repeated here. A person of ordinary skill in the art can realize that the various modules described in conjunction with the embodiments disclosed in the present application can be implemented on hardware, software, or a combination of both. Whether these functions are performed on hardware or software depends on the particular application and design constraints of the technical solution. The skilled professional may use a different method for each particular application to implement the described functions, but such implementation should not be considered as going beyond the scope of the present application.

The apparatus for measuring reading time of a sequential circuit provided in Embodiment 3 of the present application is based on the oscillation ring circuits provided in Embodiment 1 and Embodiment 2 of the present application, where the oscillation ring circuit provided in Embodiment 1 is used as the comparative unit, and the oscillation ring circuit provided in Embodiment 2 is used as the test unit, which has a clear layout and a simple structure. And according to the change obtained by comparing the oscillation periods of the feedback level waveforms outputted by the comparative unit and the test unit, the time delay of the complex sequential circuit to be measured can be measured. The apparatus for measuring reading time of a sequential circuit on a hardware circuit is provided, which has a simple structure, and a more accurate performance indicator of the actual circuit is obtained and simulation data is corrected.

### Embodiment 4

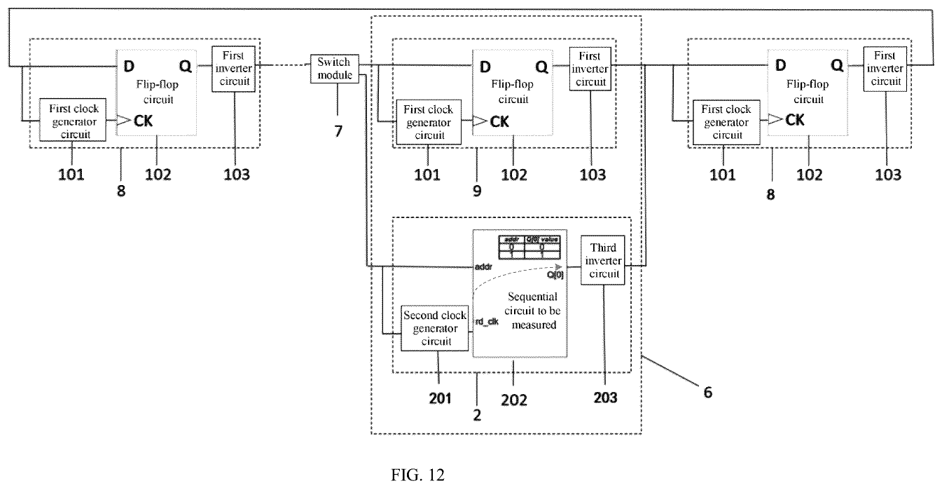

As shown in FIG. 12, according to the oscillation ring circuits provided in Embodiment 1 and Embodiment 2 of the present application, the present application also provides an apparatus of a second type for measuring reading time of a sequential circuit. The apparatus includes a test module, a switch module and first oscillatory circuits 8 which are sequentially connected in series;
the test module 6 includes a second oscillatory circuit 9 and a circuit 2 to be measured connected in parallel;
the first oscillatory circuits 8 and the second oscillatory circuit 9 are the oscillatory circuits as described in the above Embodiment 1 and Embodiment 2; the circuit 2 to be measured is the circuit to be measured as described in the above Embodiment 2;
an input end of the switch module 7 is connected to an output end of one of the first oscillatory circuits 8, and the switch module 7 includes two output ends, one of which is connected to an input end of the second oscillatory circuit 9, and the other of which is connected to an input end of the circuit 2 to be measured;
an output end of the second oscillatory circuit 9 and an output end of the circuit 2 to be measured are connected to an input end of another first oscillatory circuit 8.

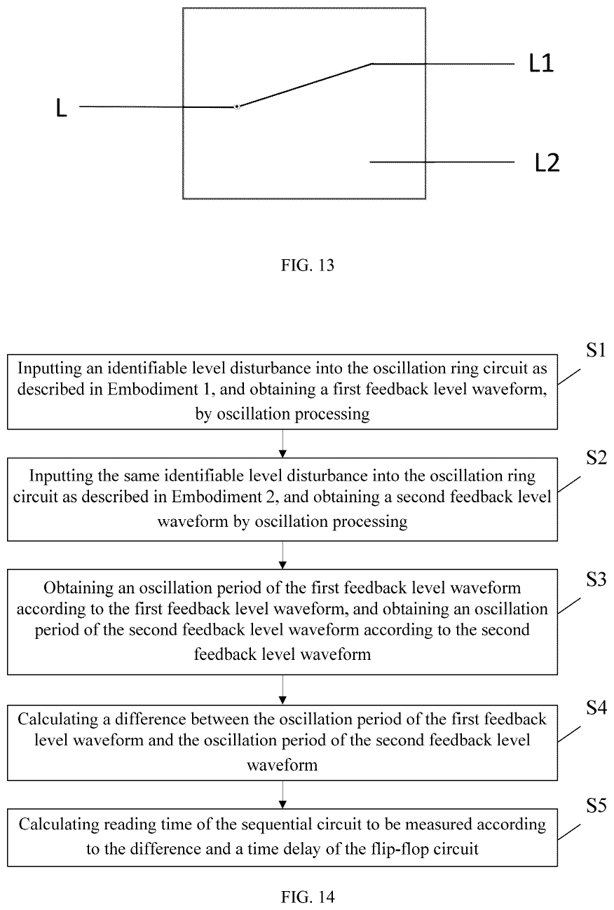

In an embodiment of the present application, the switch module 7 may employ a dual-control switch, as shown in FIG. 13. The dual-control switch is also called a dual-gang switch and includes three terminals, one of which is a common terminal L. When the switch is toggled, the common terminal L is connected to or disconnected from the other two terminals L1 and L2. Two single-control switches may also be used, one of which is connected in series with the second oscillatory circuit 9 for controlling connection or disconnection of the first oscillatory circuit 8 to the second oscillatory circuit 9, and the other of which is connected in series with the circuit 2 to be measured for controlling connection or disconnection of the first oscillatory circuit 8 to the circuit 2 to be measured.

In this embodiment of the present application, the first oscillatory circuits which are the same as the oscillatory circuits in Embodiment 1 and Embodiment 2 are used as a common portion of the apparatus for measuring reading time of a sequential circuit, and the second oscillatory circuit which is the same as the oscillatory circuit in Embodiment 1 and Embodiment 2 and the circuit to be measured which is the same as the circuit to be measured in Embodiment 2, are connected in parallel. Switching of the second oscillatory circuit and the circuit to be measured is realized by the switch module, and the oscillation ring circuit of the first type and the oscillation ring circuit of the second type provided in the present application are integrated together, thereby further simplifying the circuit structure.

### Embodiment 5

As shown in FIG. 14, according to the oscillation ring circuits provided in Embodiment 1 and Embodiment 2 of the present application, the present application also provides a method of a first type for measuring reading time of a sequential circuit.

The method includes the following steps.

S1, inputting an identifiable level disturbance into the oscillation ring circuit of the first type as described in Embodiment 1, and obtaining a first feedback level waveform by oscillation processing.

S2, inputting the same identifiable level disturbance into the oscillation ring circuit of the second type as described in Embodiment 2, and obtaining a second feedback level waveform by oscillation processing.

S3, obtaining an oscillation period of the first feedback level waveform according to the first feedback level waveform, and obtaining an oscillation period of the second feedback level waveform according to the second feedback level waveform.

S4, calculating a difference between the oscillation period of the first feedback level waveform and the oscillation period of the second feedback level waveform.

S5, calculating reading time of the sequential circuit to be measured according to the difference and a time delay of the flip-flop circuit.

On the basis of the oscillation ring circuits provided in Embodiment 1 and Embodiment 2 of the present application, the reading time of the sequential circuit to be measured is measured. The same level disturbance is input into the oscillation ring circuit of the first type and the oscillation ring circuit of the second type, respectively, and the first feedback level waveform outputted by the oscillation ring circuit of the first type and the second feedback level waveform outputted by the oscillation ring circuit of the second type are obtained. The corresponding oscillation period of the first feedback level waveform and the corresponding oscillation period of the second feedback level waveform are calculated and obtained according to the first feedback level waveform and the second feedback level waveform. The difference between the oscillation period of the first feedback level waveform and the oscillation period of the second feedback level waveform is calculated, and this difference is an actual measured difference.

In another possible embodiment of the present application, the reading time of the sequential circuit to be measured is calculated by the formula:

$${Tcq}^{′} = Tdelta / 2 + T c q ,$$

where Tdelta denotes the difference between the oscillation period of the second feedback level waveform and the oscillation period of the first feedback level waveform, and Tcq denotes the time delay of the flip-flop circuit.

Within the oscillation ring circuit of the first type, once the oscillation ring circuit of the first type starts oscillating, the frequency of its feedback level waveform is determined by the sum of a time delay of the exclusive-OR gate circuit in each of the first clock generator circuits plus time delays from the clock signal input ends CK of all the flip-flop circuits to their data output ends Q. The time delay from the clock signal input end CK of the flip-flop circuit to its data output end Q is an internal time delay of the flip-flop circuit, that is, access time of the flip-flop circuit. For the flip-flop circuits, reading and writing operations are uniform, therefore memory time and reading time will not be discriminated, and instead, they are combined as the access time.

Therefore, the oscillation period of the first feedback level waveform corresponding to the first feedback level waveform outputted by the oscillation ring circuit of the first type is:

$$Tcycle = ( Tcg + T cq ) ⋆ A ⋆ 2 = ( Tcg + T cq ) ⋆ 2 A ,$$

where Tcycle is the oscillation period of the first feedback level waveform, Tcg is the time delay of the first clock generator circuit, Tcq is the time delay of the flip-flop circuit, and A denotes the number of the oscillatory circuits.

Within the oscillation ring circuit of the second type, once the oscillation ring circuit of the second type starts oscillating, the frequency of the feedback level waveform is determined by the sum of a time delay of each of the oscillatory circuits and a time delay of the circuit to be measured. The time delay of each oscillatory circuit is determined by the sum of a time delay of the exclusive-OR gate circuit in the first clock generator circuit thereof plus a time delay from the clock signal input end CK of the flip-flop circuit thereof to its data output end Q. The time delay of the circuit to be measured is determined by the sum of a time delay of the exclusive-OR gate circuit in the second clock generator circuit thereof plus a time delay from the clock signal input end rd_clk of the sequential circuit to be measured thereof to its data output end Q[0].

Therefore, the oscillation period of the second feedback level waveform corresponding to the first feedback level waveform outputted by the oscillation ring circuit of the second type is:

$${Tcycle}^{′} = ( Tcg + T cq ) ⋆ 2 ⋆ ( A - 1 ) + 2 ( T cg + {Tcq}^{′} ) ,$$

where Tcycle′ is the oscillation period of the second feedback level waveform, Tcq′ denotes the circuit time delay from the clock input end (rd_clk) of the sequential circuit to be measured to its data output end (Q[0]).

When three oscillatory circuits are used to form the oscillation ring circuit, the oscillation period of the first feedback level waveform of the oscillation ring circuit of the first type can be expressed as:

$$Tcycle = ( Tcg + T cq ) ⋆ 3 ⋆ 2 = ( Tcg + T cq ) ⋆ 6 ,$$

the oscillation period of the second feedback level waveform of the oscillation ring circuit of the second type can be expressed as:

$${Tcycle}^{′} = 4 ( T c g + T c q ) + 2 ( T cg + {Tcq}^{′} ) ,$$

the difference Tdelta between Tcycle′ and Tcycle is calculated as:

$$Tdelta = {Tcycle}^{′} - Tcycle = 4 ( T c g + T c q ) + 2 ( T cg + {Tcq}^{′} ) - 6 ( T c g + T cq )$$

$$= 2 {Tcq}^{′} - 2 Tcq .$$

When five oscillatory circuits are used to form the oscillation ring circuit, the oscillation period of the first feedback level waveform of the oscillation ring circuit of the first type can be expressed as:

$$Tcycle = ( Tcg + T cq ) ⋆ 5 ⋆ 2 = ( Tcg + T cq ) ⋆ 10 ,$$

the oscillation period of the second feedback level waveform of the oscillation ring circuit of the second type can be expressed as:

$${Tcycle}^{′} = 8 ( T c g + T c q ) + 2 ( T cg + {Tcq}^{′} ) ,$$

the difference Tdelta between Tcycle′ and Tcycle is calculated as:

$$Tdelta = {Tcycle}^{′} - Tcycle = 8 ( T c g + T c q ) + 2 ( T cg + {Tcq}^{′} ) - 10 ( T c g + T cq )$$

$$= 2 {Tcq}^{′} - 2 Tcq .$$

Therefore, the difference between Tcycle′ and Tcycle is independent of the number of the oscillatory circuits, so no matter how many oscillatory circuits are used to form the oscillation ring circuit, the difference between Tcycle′ and Tcycle is expressed by the following formula: Tdelta=2Tcq′−2Tcq.

The circuit structure of the flip-flop circuit is relatively simple, and more accurate and reliable values can be obtained by simulation. The simulation method for obtaining the time delay of the flip-flop circuit belongs to the prior art and will not be repeated in the embodiments of the present application.

Therefore, the formula for calculating the reading time of the sequential circuit to be measured is:

$${Tcq}^{′} = Tdelta / 2 + T c q .$$

Based on the oscillation ring circuits provided in Embodiment 1 and Embodiment 2 of the present application, Embodiment 5 of the present application provides a method for measuring reading time of a sequential circuit. The method can measure the time delay of the complex sequential circuit to be measured according to the change obtained by comparing the oscillation periods of the feedback level waveforms outputted by the oscillation ring circuit of the first type and the oscillation ring circuit of the second type. The method for measuring reading time of a sequential circuit on a hardware circuit is provided, which is easy to implement and has a simple structure, and a more accurate performance indicator of the actual circuit is obtained and simulation data is corrected.

In summary, the embodiments of the present application provide oscillation ring circuits and an apparatus and method for measuring reading time of a sequential circuit. Among them, an oscillation ring circuit of one type is formed by an odd number of identical oscillatory circuits sequentially connected in series, each of which includes a first clock generator circuit, a flip-flop circuit and a first inverter circuit sequentially connected in series; within an oscillatory circuit, an output end of the first clock generator circuit is connected to a clock signal input end of the flip-flop circuit; a data output end of the flip-flop circuit is connected to an input end of the first inverter circuit; an output end of the first inverter circuit is connected to an input end of the first clock generator circuit and a data input end of the flip-flop circuit within another oscillatory circuit. An oscillation ring circuit of another type is formed by replacing one of the flip-flop circuits therein with a sequential circuit to be measured. In the present application, the reading time of the sequential circuit to be measured is measured according to the changes in the oscillation periods of the feedback level waveforms of the two types of oscillation ring circuits. Measurement of the reading time of the sequential circuit is realized on a hardware circuit, which is simple in structure and accurate in measurement, and simulation data is corrected.

The above embodiments describe only several preferred implementations of the present application in a specific and detailed way. However, they are not to be construed as limitations on the scope of the patent application. It should be pointed out that for a person of ordinary skill in the art, several improvements and substitutions can be made without departing from the technical principles of the present application, and these improvements and substitutions should also be regarded as falling within the scope of protection of the present application. Therefore, the scope of protection of the patent application shall be subject to the scope of protection of the claims.

What is claimed is:

1. A first oscillation ring circuit, comprising an odd number of identical oscillatory circuits, wherein the oscillatory circuits are sequentially connected in series to form the first oscillation ring circuit, each of the oscillatory circuits comprises a first clock generator circuit, a flip-flop circuit and a first inverter circuit, and the number of the oscillatory circuits is at least three; wherein,
within an oscillatory circuit, an output end of the first clock generator circuit is connected to a clock signal input end of the flip-flop circuit; a data output end of the flip-flop circuit is connected to an input end of the first inverter circuit;
an output end of the first inverter circuit is connected to an input end of the first clock generator circuit within another oscillatory circuit and a data input end of the flip-flop circuit within the another oscillatory circuit.

2. The first oscillation ring circuit according to claim 1, wherein the first clock generator circuit comprises a second inverter circuit and an exclusive-OR gate circuit; wherein,
an output end of the second inverter circuit is connected to a first input end of the exclusive-OR gate circuit;
an output end of the exclusive-OR gate circuit is connected to the clock signal input end of the flip-flop circuit within a respective oscillatory circuit;
an input end of the second inverter circuit and a second input end of the exclusive-OR gate circuit are both connected to the output end of the first inverter circuit within another oscillatory circuit.

3. The first oscillation ring circuit according to claim 2, wherein the first inverter circuit and the second inverter circuit are identical.

4. The first oscillation ring circuit according to claim 1, wherein the oscillatory circuits comprise three oscillatory circuits.

5. The first oscillation ring circuit according to claim 2, wherein a time delay of the second inverter circuit is larger than a minimum pulse width of the flip-flop circuit.

6. A second oscillation ring circuit, comprising an even number of oscillatory circuits and a circuit to be measured, wherein the circuit to be measured is connected in series with the oscillatory circuits to form the second oscillation ring circuit, each of the oscillatory circuits comprises a first clock generator circuit, a flip-flop circuit and a first inverter circuit, and the circuit to be measured comprises a second clock generator circuit, a sequential circuit to be measured and a third inverter circuit; wherein,
within an oscillatory circuit, an output end of the first clock generator circuit is connected to a clock signal input end of the flip-flop circuit; a data output end of the flip-flop circuit is connected to an input end of the first inverter circuit;
an output end of the first inverter circuit is connected to an input end of the first clock generator circuit within another oscillatory circuit and a data input end of the flip-flop circuit within the another oscillatory circuit, or to an input end of the second clock generator circuit within the circuit to be measured and an address input end of the sequential circuit to be measured within the circuit to be measured;
an output end of the second clock generator circuit within the circuit to be measured is connected to a clock signal input end of the sequential circuit to be measured;
a data output end of the sequential circuit to be measured is connected to an input end of the third inverter circuit;
an output end of the third inverter circuit is connected to an input end of the first clock generator circuit within any oscillatory circuit and a data input end of the flip-flop circuit within the any oscillatory circuit.

7. The second oscillation ring circuit according to claim 6, wherein the first clock generator circuit and the second clock generator circuit each comprise a second inverter circuit and an exclusive-OR gate circuit, wherein,
an output end of the second inverter circuit is connected to a first input end of the exclusive-OR gate circuit;
an output end of the exclusive-OR gate circuit is connected to a clock signal input end of the flip-flop circuit within a respective oscillatory circuit or the clock signal input end of the sequential circuit to be measured;
an input end of the second inverter circuit and a second input end of the exclusive-OR gate circuit are both connected to an output end of the first inverter circuit within another oscillatory circuit or an output end of the third inverter circuit within the circuit to be measured.

8. The second oscillation ring circuit according to claim 7, wherein the first inverter circuit, the second inverter circuit and the third inverter circuit are identical.

9. The second oscillation ring circuit according to claim 6, wherein the oscillatory circuits comprise two oscillatory circuits.

10. The second oscillation ring circuit according to claim 6, wherein the sequential circuit to be measured comprises an on-chip memory circuit.

11. The second oscillation ring circuit according to claim 7, wherein a time delay of the second inverter circuit is larger than a minimum pulse width of the flip-flop circuit.

12. An apparatus for measuring reading time of a sequential circuit, wherein the apparatus comprises a comparative unit and a test unit, wherein,
the comparative unit comprises a first oscillation ring circuit, wherein the first oscillation ring circuit comprises an odd number of identical oscillatory circuits, wherein the oscillatory circuits are sequentially connected in series to form the first oscillation ring circuit, each of the oscillatory circuits comprises a first clock generator circuit, a flip-flop circuit and a first inverter circuit, and the number of the oscillatory circuits is at least three; wherein, within an oscillatory circuit, an output end of the first clock generator circuit is connected to a clock signal input end of the flip-flop circuit; a data output end of the flip-flop circuit is connected to an input end of the first inverter circuit; an output end of the first inverter circuit is connected to an input end of the first clock generator circuit within another oscillatory circuit and a data input end of the flip-flop circuit within the another oscillatory circuit;
the test unit comprises the second oscillation ring circuit according to claim 6.

13. The apparatus for measuring reading time of a sequential circuit according to claim 12, wherein the apparatus further comprises a data processing unit, and the data processing unit is connected to the comparative unit and test unit respectively;
the comparative unit is configured to output a first feedback level waveform according to an inputted identifiable level disturbance;
the test unit is configured to output a second feedback level waveform according to the same inputted identifiable level disturbance;
the data processing unit is configured to: obtain an oscillation period of the first feedback level waveform according to the first feedback level waveform, and obtain an oscillation period of the second feedback level waveform according to the second feedback level waveform; calculate a difference between the oscillation period of the first feedback level waveform and the oscillation period of the second feedback level waveform; calculate reading time of the sequential circuit to be measured according to the difference and a time delay of the flip-flop circuit.

14. The apparatus for measuring reading time of a sequential circuit according to claim 13, wherein the reading time of the sequential circuit to be measured is calculated by the following formula:
$${Tcq}^{′} = Tdelta / 2 + T c q ,$$
wherein Tdelta denotes the difference between the oscillation period of the second feedback level waveform and the oscillation period of the first feedback level waveform, and Tcq denotes the time delay of the flip-flop circuit.

15. An apparatus for measuring reading time of a sequential circuit, wherein the apparatus comprises a test module, a switch module and first oscillatory circuits which are sequentially connected in series;
the test module comprises a second oscillatory circuit and a circuit to be measured which are connected in parallel;
each of the first oscillatory circuits and the second oscillatory circuit is an oscillatory circuit comprising a first clock generator circuit, a flip-flop circuit and a first inverter circuit; wherein within the oscillatory circuit, an output end of the first clock generator circuit is connected to a clock signal input end of the flip-flop circuit; a data output end of the flip-flop circuit is connected to an input end of the first inverter circuit; an output end of the first inverter circuit is connected to an input end of the first clock generator circuit within another oscillatory circuit and a data input end of the flip-flop circuit within the another oscillatory circuit; the circuit to be measured is the circuit to be measured according to claim 6;
an input end of the switch module is connected to an output end of one of the first oscillatory circuits, and the switch module comprises two output ends, one of which is connected to an input end of the second oscillatory circuit, and the other of which is connected to an input end of the circuit to be measured;
an output end of the second oscillatory circuit and an output end of the circuit to be measured are both connected to an input end of another first oscillatory circuit.

16. The apparatus for measuring reading time of a sequential circuit according to claim 15, wherein the first clock generator circuit and the second clock generator circuit each comprises a second inverter circuit and an exclusive-OR gate circuit; wherein,
an output end of the second inverter circuit is connected to a first input end of the exclusive-OR gate circuit;
an output end of the exclusive-OR gate circuit is connected to the clock signal input end of the flip-flop circuit within a respective oscillatory circuit or the clock signal input end of the sequential circuit to be measured;
an input end of the second inverter circuit and a second input end of the exclusive-OR gate circuit are both connected to the output end of the first inverter circuit within another oscillatory circuit, or to an output end of the third inverter circuit within the circuit to be measured, or to one of the two output ends of the switch module.

17. The apparatus for measuring reading time of a sequential circuit according to claim 16, wherein the first inverter circuit, the second inverter circuit and the third inverter circuit are identical.

18. The apparatus for measuring reading time of a sequential circuit according to claim 16, wherein a time delay of the second inverter circuit is larger than a minimum pulse width of the flip-flop circuit.

19. A method for measuring reading time of a sequential circuit, wherein the method comprises:
inputting an identifiable level disturbance into a first oscillation ring circuit, and obtaining a first feedback level waveform by oscillation processing;
inputting the same identifiable level disturbance into the second oscillation ring circuit according to claim 6, and obtaining a second feedback level waveform by oscillation processing;
obtaining an oscillation period of the first feedback level waveform according to the first feedback level waveform, and obtaining an oscillation period of the second feedback level waveform according to the second feedback level waveform;
calculating a difference between the oscillation period of the first feedback level waveform and the oscillation period of the second feedback level waveform;
calculating reading time of the sequential circuit to be measured according to the difference and a time delay of the flip-flop circuit;
wherein the first oscillation ring circuit comprises an odd number of identical oscillatory circuits, wherein the oscillatory circuits are sequentially connected in series to form the first oscillation ring circuit, each of the oscillatory circuits comprises a first clock generator circuit, a flip-flop circuit and a first inverter circuit, and the number of the oscillatory circuits is at least three; wherein, within an oscillatory circuit, an output end of the first clock generator circuit is connected to a clock signal input end of the flip-flop circuit; a data output end of the flip-flop circuit is connected to an input end of the first inverter circuit; an output end of the first inverter circuit is connected to an input end of the first clock generator circuit within another oscillatory circuit and a data input end of the flip-flop circuit within the another oscillatory circuit.

20. The method for measuring reading time of a sequential circuit according to claim 19, wherein the reading time of the sequential circuit to be measured is calculated by the following formula:
$${Tcq}^{′} = Tdelta / 2 + T c q ,$$
wherein Tdelta denotes the difference between the oscillation period of the second feedback level waveform and the oscillation period of the first feedback level waveform, and Tcq denotes the time delay of the flip-flop circuit.
